(19) United States
(12) Patent Application Publication
(10) Pub. No.: US 2013/0214497 A1
(43) Pub. Date: Aug. 22, 2013

(54) SUBSTRATE ROTATION HOLDING APPARATUS AND SUBSTRATE PROCESSING APPARATUS

(71) Applicant: Kabushiki Kaisha Toshiba, (US)

(72) Inventor: Kenji Yoshida, Oita-ken (JP)

(73) Assignee: Kabushiki Kaisha Toshiba, Tokyo (JP)

(21) Appl. No.: 13/729,513

(22) Filed: Dec. 28, 2012

(30) Foreign Application Priority Data
Feb. 20, 2012 (JP) 2012-033977

(51) Int. Cl. H01L 21/687

(52) U.S. Cl. CPC H01L 21/68728
USPC 279/131

(57) ABSTRACT

An aspect of one embodiment, there is provided a substrate rotation holding apparatus, including a substrate holding section configured to hold a substrate by sandwiching around an outer periphery end portion of the substrate with a disk shape by a plurality of holding members, each of the holding members having a contact surface with the substrate, the contact surface being a concave curvature surface, and a rotation driving section configured to rotate the substrate holding section.

### CROSS REFERENCE TO RELATED APPLICATION

This application is based upon and claims the benefit of priority from prior Japanese Patent Application No. 2012-033977, filed on Feb. 20, 2012, the entire contents of which are incorporated herein by reference.

### FIELD

Exemplary embodiments described herein generally relate to a substrate rotation holding apparatus and a substrate processing apparatus.

### BACKGROUND

Conventionally, a substrate processing apparatus such as a substrate cleaning apparatus has been known. The substrate cleaning apparatus performs cleaning a substrate such as a wafer while the substrate is rotating. In such the substrate processing apparatus, for example, a plurality of holding members disposed at a substrate holding section sandwiches around an outer periphery end portion of the substrate. In such a manner, the substrate holding section is rotated so as to rotate the substrate and resulting in cleaning the substrate in rotating by brush or the like.

Embodiments provide a substrate rotation holding apparatus and a substrate processing apparatus both of which can solve to suitably hold the substrate in the cleaning process.

### BRIEF DESCRIPTION OF THE DRAWINGS

FIG. 1 is a schematic view showing a constitution of a substrate processing apparatus according to a first embodiment;

FIG. 2 is a schematic view showing a constitution of a chuck pin in FIG. 1 according to the first embodiment;

FIG. 3 is a schematic plane view showing a substrate rotation holding apparatus in the substrate processing apparatus in FIG. 1 according to the first embodiment;

FIG. 4 is a schematic plane view showing a relationship between the chuck pin and a cleaning brush according to the first embodiment;

FIG. 5 is a schematic plane view showing an end portion of the A-A line in FIG. 2 according to the first embodiment;

FIG. 6 is a schematic side view showing a state of holding a substrate by the chuck pin according to the first embodiment;

FIG. 7 is a schematic side view showing an action of holding the substrate by the chuck pin according to the first embodiment;

FIG. 8 is a schematic side view showing an action of holding the substrate by the chuck pin according to the first embodiment;

FIG. 9 is a schematic side view showing a substrate contact section in the chuck pin according to a second embodiment.

### BRIEF DESCRIPTION OF THE DRAWINGS

An aspect of one embodiment, there is provided a substrate rotation holding apparatus, including a substrate holding section configured to hold a substrate by sandwiching around an outer periphery end portion of the substrate with a disk shape by a plurality of holding members, each of the holding members having a contact surface with the substrate, the contact surface being a concave curvature surface, and a rotation driving section configured to rotate the substrate holding section.

An another aspect of one embodiment, there is provided a substrate processing apparatus, including a substrate holding section configured to hold a substrate by sandwiching around an outer periphery end portion of the substrate with a disk shape by a plurality of holding members, each of the holding members having a contact surface with the substrate, the contact surface being a concave curvature surface, and a rotation driving section configured to rotate the substrate holding section.

Embodiments will be described below in detail with reference to the attached drawings mentioned above. Throughout the attached drawings, similar or same reference numerals show similar, equivalent or same components.

### First Embodiment

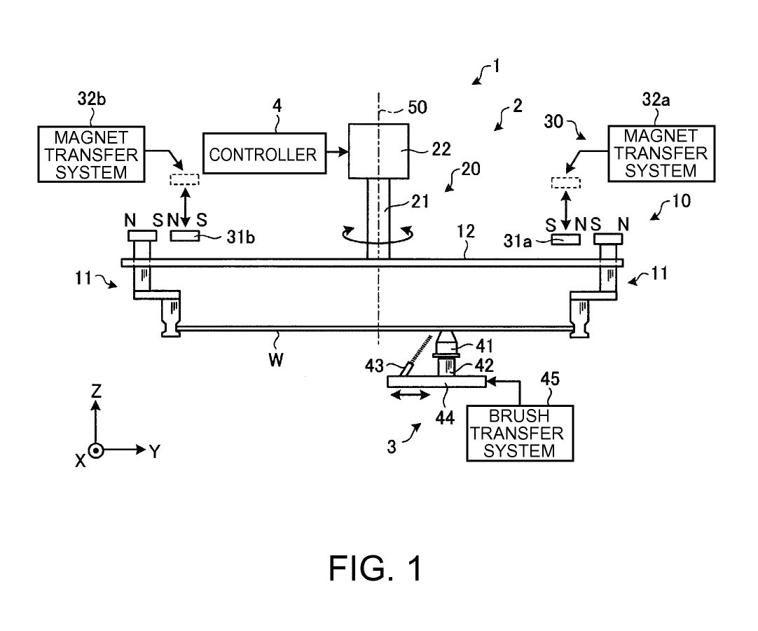

A substrate processing apparatus according to a first embodiment is specifically described by using FIGS. 1-8.

In FIGS. 1-6, arrows indicating X-direction, Y-direction and Z-direction, which are orthogonal each other, are added to clarify position relations between constitution elements in the substrate processing apparatus. Here, the embodiment is explained where the Z-direction is set in upper-down direction. However, the embodiment of the substrate processing apparatus is not restricted to the apparatus in FIG. 1.

A constitution of the substrate processing apparatus according to the first embodiment is described by using FIGS. 1-4. FIG. 1 is a schematic view showing a constitution of the substrate processing apparatus.

As shown in FIG. 1, the substrate processing apparatus 1 includes a substrate rotation holding apparatus 2, a cleaning apparatus 3 and a controller 4. The substrate rotation holding apparatus 2 configured to hold a substrate W with a disk shape, such as a wafer, to rotate the substrate W around a rotational axis 50. The cleaning apparatus 3 is configured to clean a back surface and an outer periphery end portion of the substrate W in a rotating state by the substrate rotation holding apparatus 2. The controller 4 is configured to control the substrate rotation holding apparatus 2 and the cleaning apparatus 3.

The substrate rotation holding apparatus 2 includes a substrate holding section 10, a rotation driving section 20 and an open-close driving unit 30. The substrate holding section 10 configured to receive the substrate W transferred from a substrate transfer section (not shown) to send the substrate W to the substrate transfer section after the substrate W is cleaned by the cleaning apparatus 3. The rotation driving section 20 is connected to the substrate holding section 10 to rotate the substrate holding section 10 around the rotation axis 50 extended to Z-direction as the center. The open-close driving unit 30 configured to control to retain and release the substrate W by the substrate holding section 10.

The substrate holding section 10 includes a plurality of chuck pins 11 and a spin plate 12, and each of the chuck pins 11 is corresponded to a holding member 11, for example. The chuck pin is disposed on the same circumference with a rotation axis 50 as the center and an equal interval is set between the adjacent chuck pins. The chuck pins 11 are supported at an outer periphery portion of the spin plate 12 with a disk shape. The spin plate 12 is connected to the rotation driving section 20 and the chuck pins 11 and the spin plate 12 are rotated around the rotation axis 50 by the rotation driving section 20.

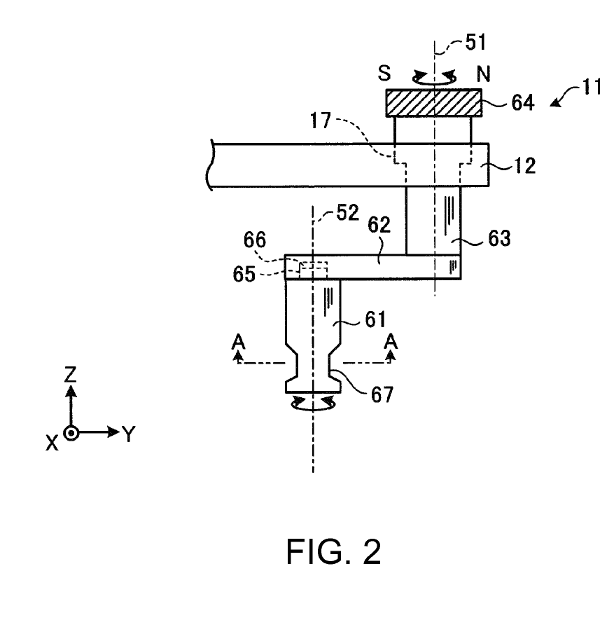

FIG. 2 is a schematic view showing a constitution of the chuck pin. As shown in FIG. 2, the chuck pin includes a holding pin 61, a pin supporting unit 62, an axis unit 63 and a magnet 64. The holding pin 61 has a substrate contact unit 67 on an under surface and is supported at a leading edge of the pin supporting unit 62. Further, a base edge of the pin supporting unit 62 is connected to an under edge of the axis unit 63. The axis unit 63 is inserted into an opening 17 of the spin plate 12 and is supported on the spin plate 12 to be allowed to rotate around the rotation axis 51. The rotation axis 51 is a vertical axis extending in Z-direction as the same as the rotation axis 50.

The magnet 64 is disposed on an upper end of the axis unit 63. As described later, the axis unit 63 is rotated around the rotation axis 51 by supplying magnetic force to the magnet 64. As shown in FIG. 2, south-pole is placed at a side of a rotation axis 50, and north-pole is placed at the opposed side setting the rotation axis 51 as a standard. In FIG. 2, the holding pin 61 is placed at the most nearest side of the rotation axis 50.

A motor 65 is disposed in the pin supporting unit 62. The holding pin 61 is configured to rotate around a rotation axis 52 by driving the motor 65. The rotation axis 52 is a vertical axis extending in Z-direction as the same as the rotation axes 50 and 51. An encoder 66 is configured in the pin supporting unit 62 to detect a rotation position of the motor 65 and detects the rotation position of the holding pin 61. In this embodiment, the holding pin 61 is rotated around the rotation axis 52 by the motor 65. However, the holding member can be constituted that a worker can change the rotation position of the holding pin 61 in multi steps. Furthermore, holding pin 61 can be rotated around the rotation axis 52 by a driving approach other than the motor 65.

Back to FIG. 1, the substrate rotation holding apparatus 2 is successively described. An open-close driving unit 30 is disposed on the upper side of the spin plate 12. The open-close driving unit 30 includes magnet plates 31a, 31b and magnet transfer systems 32a, 32b.

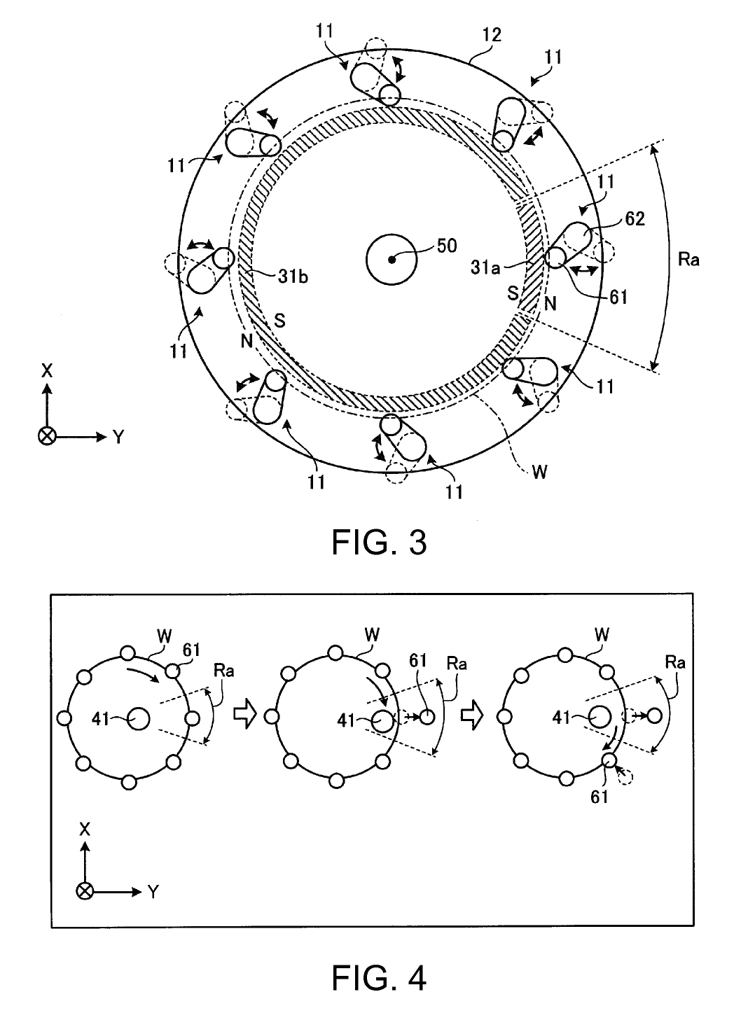

FIG. 3 is a schematic plane view of the substrate rotation holding apparatus 2. The rotation driving section 20 is not illustrated in FIG. 3 to easily understand the explanation. As shown in FIG. 3, the magnet plate 31a, 31b are disposed in a circumference direction around the rotation axis 50 as the center. In the magnet plate 31a, 31b, north-pole is configured at an outer side of a periphery and south-pole is configured at an inner side of the periphery. The magnet plate 31a supplies magnetic force to a chuck pin 11 in a region Ra and the magnet plate 31b supplies magnetic force to a chuck pin 11 a region other than a region Ra.

Furthermore, the magnet plates 31a, 31b independently shift in upper and lower directions by the magnet transfer systems 32a, 32b, respectively. Specifically, the magnet plates 31a, 31b are shifted to a set position, which is nearly the same height as the magnet 64 of the chuck pin 11, by the magnet transfer systems 32a, 32b, and are shifted to a reset position, which is an upper position being apart a predetermined distance from the magnet 64.

As described above, north-pole is configured at the outer periphery side of the magnet plates 31a, 31b.

Accordingly, when the magnet plates 31a, 31b is shifted from the reset position to the set position, south-pole of the magnet 64 in the chuck pin 11 is attracted to the magnet plates 31a, 31b.

Therefore, the holding pin 61 is shifted to a side of the rotation axis 50 than that of the rotation axis 51 so as to be set a state in which the substrate W can be retained. The state is illustrated as a position described by a real line in the FIG. 3, which is called a retention state.

On the other hand, when the magnet plates 31a, 31b is shifted from the set position to the reset position, the magnet 64 in the chuck pin 11 is not attracted to the magnet plate 31a, 31b. Therefore, a state, in which south-pole of the chuck pin 11 in the magnet 64 is attracted to the magnet plates 31a, 31b, is released. In a state that magnetic force of the magnet plate 31a, 31b is not influenced to the chuck pin 11, the opposed force is added to the holding pin 61 to be positioned to the side of the rotation axis 50 than that of the rotation axis 51. Accordingly, holding pin 61 is shifted to the opposed side of the rotation axis 50 to the rotation axis 51 so as to not to retain the substrate W. The state is illustrated as a position described by a dotted line in the FIG. 3, which is called a release state.

In such a manner, the magnet plates 31a, 31b are shifted from the reset position to the set position so that the holding pin 61 in the chuck pins 11 is set to be the retention state in the substrate holding section 10. As a result, the substrate W is sandwiched by the holding pin 61 to be held. On the other hand, the magnet plates 31a, 31b are set from the set state to the reset state so that the holding pin 61 in the chuck pins 11 is set to be the release state. As a result, holding the substrate W by the chuck pin 11 is released.

Furthermore, the holding pin 61 in the chuck pins 11 positioned in a region Ra as shown in FIG. 3 can be released. In the state described above, the magnet plates 31a, 31b in the substrate holding section 10 are set to be the set position so as to hold the substrate W, subsequently, the magnet plate 31a is set to be the reset position. In such a manner, an outer periphery end portion of the substrate W can be cleaned as described later.

Back to FIG. 1, the substrate rotation holding apparatus 2 is successively described. The substrate holding section 10 described above rotates around the rotation axis 50 by the rotation driving section 20. The rotation driving section 20 includes an axis unit 21 and a driving section 22. A reading edge of the axis section 21 is connected to a center of the spin plate 12 in the substrate holding section 10. On the other hand, a basic edge of the axis section 21 is connected to the driving section 22. The axis section 21 is rotated around the rotation axis 50 by driving of the driving section 22. The driving section 22 is constituted with a motor or a reducer, for example.

Next, the cleaning apparatus 3 is described.

As shown in FIG. 1, the cleaning apparatus 3 includes a cleaning brush 41, a motor 42, a cleaning nozzle 43, a holding member 44 and a brush transfer system 45. The cleaning brush 41 is approximately a cylinder brush and the cleaning brush 41 is fixed to the holding member 44 so as to be assembled to a rotation shaft of the motor 42.

The rotation shaft of the motor 42 is extended in Z-direction and the cleaning brush 41 rotates the vertical axis extending in Z-axis.

The cleaning nozzle 43 is assembled near the motor 42.on the holding member 44 and a supplying pipe being supplied a cleaning solution is connected to the cleaning nozzle 43. A leading edge of the cleaning nozzle 43 faces to a periphery of the cleaning brush 41 and sprays the cleaning solution to the periphery of the cleaning brush 41. In addition, pure water or chemical, for example, is used as the cleaning solution.

The brush transfer system 45 is configured to shift the holding member 44, on which the cleaning brush 41 and the cleaning nozzle 43 are assembled, in both an upper and a lower direction and a horizontal direction. In such a manner, a side of a back surface and an outer periphery end portion of the substrate W retained by the substrate rotation holding apparatus 2 can be cleaned.

In the state described above, the magnet plates 31a, 31b in the substrate holding section 10 are set to be the set position so as to hold the substrate W, subsequently, the magnet plate 31a is set to be the reset position so that the holding pin 61 in the region Ra as shown in FIG. 3 can be released. In such a manner, the outer periphery of the back surface and the outer periphery end portion of the substrate W can be cleaned. Detail on the point described above is explained below by using FIG. 4.

FIG. 4 is a schematic plane view showing a relation ship between the chuck pin 11 and the cleaning brush 41. In a left side figure, the magnet plates 31a, 31b are set at the set position to hold the substrate W and the center of the back surface of the substrate W is cleaned by the cleaning brush 41. As the holding pin 61 is undisturbedly set to the cleaning brush 41 in such a state, the substrate W is held by the holding pin 61 in the chuck pins 11.

However, the holding pin 61 in the chuck pins 11 interrupts in cleaning the periphery of the back surface and the outer periphery end portion of the substrate W in the state. As shown in a center figure in FIG. 4, the magnet plate 31a is set to be the reset state and the holding pin 61 in the region Ra is released. As the substrate W held by the substrate holding section 10 is rotated by the rotation driving section 20, the periphery of the back surface and the outer periphery end portion of the substrate W can be cleaned by shifting the cleaning brush 41 to the region Ra.

Furthermore, as the substrate holding section 10 is rotated in cleaning, each of the chuck pins 11 shifts to an outside of the region Ra after shifting to the region Ra in an order. As the magnet plates 31b other than the region Ra are set to be the set position, the holding pin 61 in the chuck pins 11 is set to the retention state from the release state when the holding pin 61 shift to the outside of the region R from the region R as shown in a light side figure in FIG. 4.

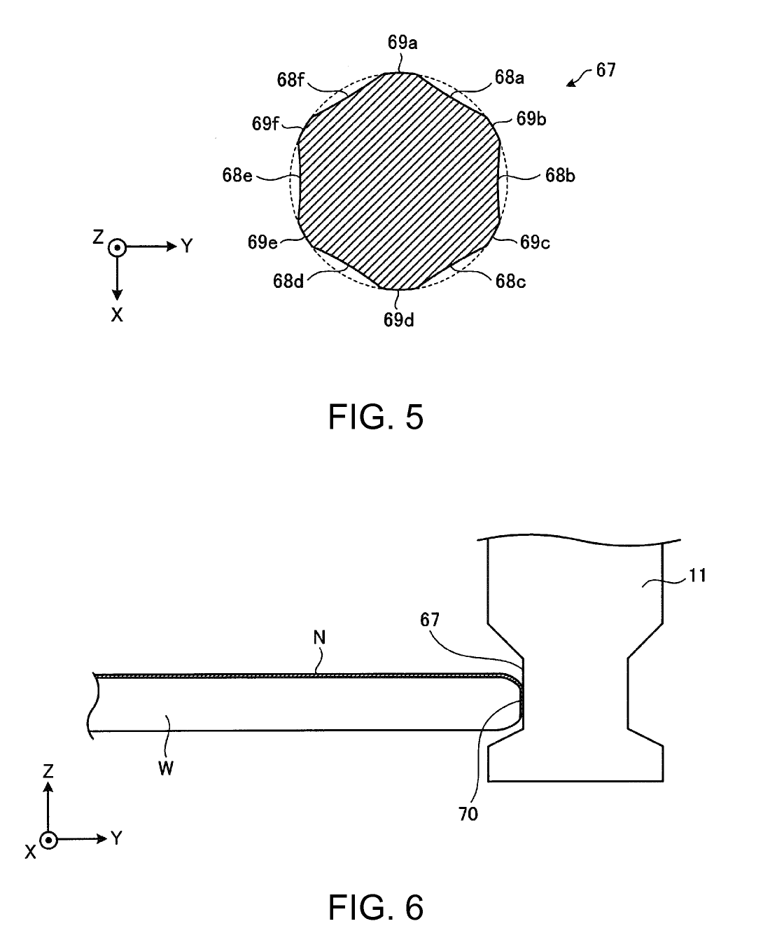

The substrate W is held by chuck pin 11 in a state that the substrate W is contacted to a substrate contact unit 67 in the holding pin 61. In the holding pin 61 of the chuck pin 11 according to the first embodiment, the substrate contact unit 67 contacting to the substrate W has a concave curvature surface, as shown in FIG. 2, to suitably hold the substrate W. The substrate contact unit 67 of the holding pin 61 is explained by using FIGS. 5-8. FIG. 5 is a schematic plane view showing an end portion of the A-A line in FIG. 2. FIG. 6 is a schematic side view showing a state of holding on a substrate by the chuck pin.

As shown in FIG. 5, a plurality of contacting surfaces 68a-68f is provided in the substrate contact unit 67 of the holding pin 61.

Each of the contacting surfaces 68a-68f has a concave curvature surface to be allowed to linearly contact to the outer periphery of the substrate W with a disk shape on X-Y plane. In other words, the substrate W has approximately the same curvature as that of the contacting surfaces 68a-68f. In such a manner, the contacting surfaces 68a-68f can be linearly contacted to the outer periphery of the substrate W with the disk-shape. Moreover, the holding pin 61 has a circle shape in cross-section other than the substrate contact unit 67

The contacting surfaces 68a-68f extend in Z-direction to enable to contact with a surface of a body having a straight fashion 70 extending in Z-direction as shown in FIG. 6. When the contacting surfaces 68a-68f are not necessary to distinguish each other, the contacting surface 68 can be used as the expression as described hereinbelow.

In such a manner, the substrate contact unit 67 of the holding pin 61 has the contacting surface 68 contacting to the substrate W on the concave curvature surface. Accordingly, the substrate contact unit 67 of the holding pin 61 has a large contacting surface to the substrate W and increasing the holding force to the substrate W, so that the substrate holding section 10 can suitably hold the substrate W.

The substrate W is rotating and the back surface of the substrate W is cleaned by a cleaning brush 41 while the cleaning process is carried out. Therefore, the substrate W is pressed and vibrated in an upper direction by the cleaning brush 41 in addition to centrifugal force by the rotation. On the other hand, the substrate W can be suppressed against out of alignment as the substrate W can be suitably held by the holding pin 61.

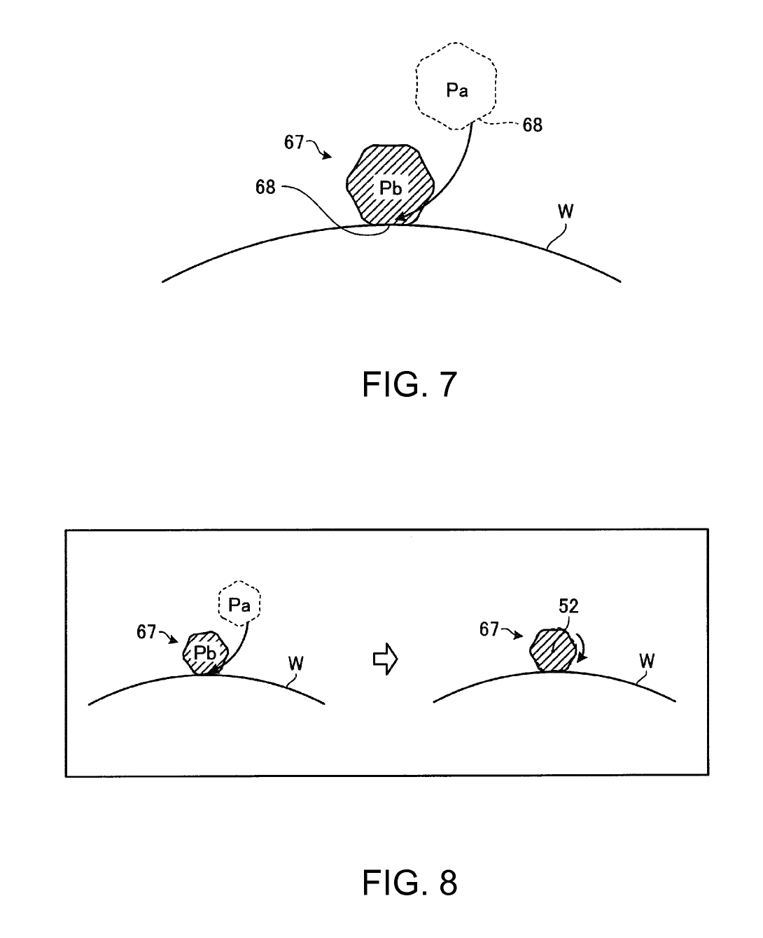

As shown in FIG. 7, even when the holding pin 61 is shifted from the release state to the retention state to shift the position of the holding pin 61 from the position Pa to the position Pb, the contacting surface of the substrate contact unit 67 contacts to the substrate W at the position Pb which is the position that the substrate contact unit 67 of the holding pin 61 is contacted to the substrate W. Therefore, a pressure applied to a unit area of the substrate contact unit 67 is suppressed to be lower, so that the locally strong pressure to the substrate contact unit 67 can be controlled. Consequently, breakage or the like of the substrate contact unit 67 can be suppressed.

On the other hand, the substrate W has the same state as the holding pin 61. As substrate W has a large contact area with the substrate contact unit 67, the pressure of a unit area applied by the substrate contact unit 67 is suppressed to be lower. As a result, a film N is suppressed to be removed from the substrate W when the film N, for example, an anti reflection film, a resist film, water repellent film, an underlying film or the like, is formed on the substrate W, as shown in FIG. 7. In such a way, contamination of the surface of the substrate W due to particles generated from the removed film N can be suppressed.

The holding pin 61 can be rotate around the rotation axis 52 by outer pressure. Therefore, when the holding pin 61 is shifted from the position Pa to the position Pb and the substrate contact unit 67 is contacted to the substrate W as shown in a left figure in FIG. 8, the holding pin 61 rotates the rotation axis 52 so that the substrate contact unit 67 is set to be in a state as shown in a right figure in FIG. 8. In other words, the substrate W is held by all the contacting surfaces 68 of the substrate contact unit 67 due to a following action of the holding pin 61. In such a manner, the substrate W can be stably held.

As described above, the chuck pin 11 includes a motor 65 in the axis unit 63 and the holding pin 61 can rotates around the rotation axis 52. The chuck pin 11 is controlled by the controller 4 to operate the motor 65 in a predetermined period so that the holding pin 61 is rotated in steps of a constant angle. The contacting surfaces 68 are repeatedly formed in the circumferential direction on the substrate contact unit 67 of the chuck pin 11. In such a manner, the contacting surface 68 to be contacted to the substrate W can be changed in a predetermined period. Accordingly, the holding pin 61 is easily retained and managed. In a case of a constitution of the substrate contact unit 67 as shown in FIG. 5, the chuck pin 11 is controlled by the controller 4 to rotate the holding pin 61 in steps of sixty degrees so that the contacting surfaces 68 are changed in an order in a predetermined period. The rotation of the holding pin 61 is controlled on a basis of the detection by the encoder 66.

A camera can be set to observe an aspect of the holding pin 61. Images of the holding pin 61 took by the camera are analyzed by the controller 4 so that the controller 4 can instruct to chuck pin 11 to shift the rotation position of the holding pin 61 on the basis of the analysis. In such a manner, the holding pin 61 can be more easily to be retained and managed.

Each of convex curvature surfaces 69a-69f, each of which is called as convex curvature surface 69 hereinafter, is formed between adjacent contacting surfaces 68 to be continuous with a curvature surface in the substrate contact unit 67 of the holding pin 61.

In such a manner, as the convex curvature surface 69 is formed, in a case that the convex curvature surface 69 is contacted to the substrate W due to misalignment of the rotation position of the holding pin 61 when the holding pin 61 is shifted from the release state to the retention state, applying a strong pressure to the substrate W can be suppressed so that abrasion and breakage of the substrate contact unit 67 can be suppressed.

As shown in FIG. 5, the contacting surface 68 and the convex curvature surface 69 are disposed that a length of the convex curvature surface 69 in the circumferential direction in the substrate contact unit 67 of the holding pin 61 is longer than that of the contacting surface 68 in the circumferential direction. As a result, when the rotation position of the substrate contact unit 67 is misalignment, contacting the contacting surface 68 to the substrate W can be quickly perform due to the following action of the holding pin 61.

As described above, the substrate holding section 10 holding the outer periphery portion of the substrate W with the disk type due to sandwiching the substrate W by chuck pins 11 and rotation driving section 20 rotating the substrate holding section 10 are included in the substrate processing apparatus 1 and the substrate rotation holding apparatus 2 according to the first embodiment. Furthermore, each of the chuck pins 11 includes the contacting surfaces 68 with the concave curvature surface to be contacted to the substrate W. Therefore, the substrate W can be suitably held to suppress generation of the particles from the substrate W and breakage or the like of the chuck pin 11, for example.

### Second Embodiment

Next, a substrate processing apparatus and a substrate rotation holding apparatus according to a second embodiment are described. A constitution in the second embodiment is basically the same as that in the first embodiment other than a shape of substrate contact section in a chuck pin.

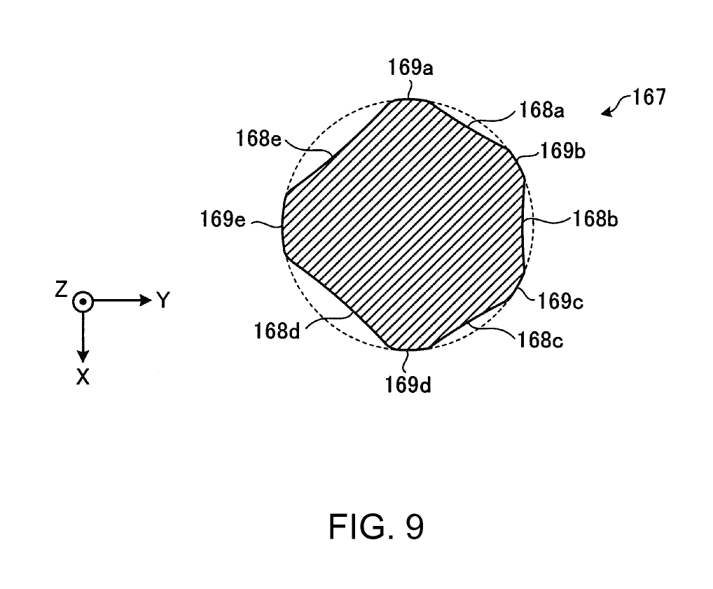

FIG. 9 is a schematic view of an end surface of a substrate contact unit in a chuck pin according to the second embodiment and is corresponded to FIG. 5 in the first embodiment.

As shown in FIG. 9, a substrate contact unit 167 of the chuck pin 11 according to the second embodiment includes second contacting surfaces 168d, 168e, each of which is called a first contacting surface 168B in addition to first contacting surfaces 168a-168c, each of which is called a first contacting surface 168A, as the same as the contacting surface 68 of the substrate contact unit 67 according to the first embodiment. The first contacting surface 168A is used for a wafer with a 300 mm diameter, for example, and the second contacting surface 168B is used for a wafer with a 450 mm diameter, for example.

The chuck pin 11 according to the second embodiment is constituted to be configured to hold substrates in which a substrate with different diameter to another substrate is included. In other words, concave curvature surfaces having different curvature each other are included in the substrate contact unit 167 according to the second embodiment. The substrate holding section 10 is controlled by the controller 4 to change a rotation position of the substrate contact unit 167 as the same as the substrate processing apparatus 1 according to the first embodiment. In such a manner, when the substrate W is constituted with a wafer with a 300 mm diameter, the rotation position of the substrate contact unit 167 of each of the chuck pins 11 is changed to be contacted to the substrate W at the first contacting surface 168A. Further, when the substrate W is constituted with a wafer with a 450 mm diameter, the rotation position of the substrate contact unit 167 of each of the chuck pins 11 is changed to be contacted to the substrate W at the first contacting surface 168B.

Accordingly, the substrates W with different diameters can be processed in the substrate processing apparatus according to the second embodiment. In such the processing, work changing the chuck pins or the like in every substrate size is not necessary to be able to improve through-put of the processing. In an example shown in FIG. 9, two kinds of curvatures of the contacting surface are used. However, the curvature is not restricted to the example described above. More than two kinds of the curvatures may be used as the chuck pins apparatus.

Each of the convex curvature surfaces 169a-169e, each of which is called as the convex curvature surface 169, is provided between the first contacting surfaces 168A, the second contacting surfaces 168B and the first contacting surface 168A and the second contacting surface 168B. As the convex curvature surface 169 is provided mentioned above, when the holding pin 61 is shifted from the release state to the retention state, in a case that the convex curvature surface 169 is contacted to the substrate W due to misalignment of the rotation position of the holding pin 61, applying a strong pressure to the substrate W can be suppressed so that abrasion and breakage of the substrate contact unit 67 can be suppressed.

In the first and second embodiments, a substrate cleaning apparatus, for example, is described as a substrate processing apparatus cleaning the back surface and the edge surface of the substrate W. However, the substrate processing apparatus is not restricted to the above apparatuses. A substrate processing apparatus may be a substrate cleaning apparatus which cleans a surface and an edge surface of the substrate.

In the embodiments described above, the substrate cleaning apparatus is described, for example, as the substrate processing apparatus. However, the substrate processing apparatus may be a coating and developing apparatus or a wet processing apparatus may be employed. When the substrate processing apparatus is the coating and developing apparatus or the wet processing apparatus, a nozzle providing chemical for a material processing a film is disposed and the chemical is provided from the nozzle while the substrate W is rotated in a retention state by the substrate rotation holding apparatus.

The substrate processing apparatus and the substrate rotation holding apparatus according to the first and embodiments are not restricted to an apparatus for fabricating a semiconductor device. The apparatuses can be employed in fabricating other than the semiconductor device. Kinds of a substrate such as a display substrate, a disk substrate, a photo mask substrate or the like other than the semiconductor substrate is used as the substrate to be held and rotated by the substrate rotation holding apparatus, so that the substrate can be processed in the substrate processing apparatus. Moreover, a liquid crystal substrate as the display substrate, a photo disk substrate, a magnetic disk substrate, and photo disk substrate as the disk substrate is employed as the substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate rotation holding apparatus, comprising:
a substrate holding section configured to hold a substrate by holding around an outer periphery end portion of the substrate with a disk shape by a plurality of holding members, each of the holding members having a contact surface with the substrate, the contact surface being a concave curvature surface; and
a rotation driving section configured to rotate the substrate holding section.

2. The substrate rotation holding apparatus of claim 1, wherein
a plurality of the concave curvature surfaces is repeatedly formed on the holding member in a circumferential direction to provide a plurality of the contacting surfaces.

3. The substrate rotation holding apparatus of claim 2, wherein
each of convex curvature surfaces is formed between adjacent convex curvature surfaces of the holding member.

4. The substrate rotation holding apparatus of claim 3, wherein
a length of the convex curvature surface in the circumferential direction is shorter than a length of the concave curvature surface in the circumferential direction.

5. The substrate rotation holding apparatus of claim 2, wherein
the holding member includes a first contacting surface and second contacting surface which has a curvature being different from a curvature of the first contacting surface.

6. The substrate rotation holding apparatus of claim 1, wherein
the curvature of the concave curvature surface is appropriately the same as a curvature of the substrate.

7. The substrate rotation holding apparatus of claim 1, wherein
the contact surface has a surface of a body with a straight fashion which extends in a vertical direction to a surface of the substrate.

8. The substrate rotation holding apparatus of claim 2, wherein
the substrate holding section includes a rotation axis being a same direction of a rotation axis of the rotation driving section and rotates each of the holding members to change the concave curvature surface contacting to the substrate.

9. The substrate rotation holding apparatus of claim 8, wherein
the holding member rotates around the rotation axis of the substrate holding section with a predetermined angle.

10. The substrate rotation holding apparatus of claim 8, wherein
the contacting surface is formed on the substrate holding section and the substrate contact section rotates around the rotation axis of the substrate holding section by pressure of an outer portion.

11. A substrate processing apparatus, comprising:
a substrate holding section configured to hold a substrate by holding around an outer periphery end portion of the substrate with a disk shape by a plurality of holding members, each of the holding members having a contact surface with the substrate, the contact surface being a concave curvature surface;
a rotation driving section configured to rotate the substrate holding section: and
a substrate processing section configured to process the substrate in a state that the substrate is rotating.

12. The substrate processing apparatus of claim 11, wherein
a plurality of the concave curvature surfaces is repeatedly formed on the holding member in a circumferential direction to provide a plurality of the contacting surfaces.

13. The substrate processing apparatus of claim 12, wherein
each of convex curvature surfaces is formed between adjacent convex curvature surfaces of the holding member.

14. The substrate processing apparatus of claim 13, wherein
a length of the convex curvature surface in the circumferential direction is shorter than a length of the concave curvature surface in the circumferential direction.

15. The substrate processing apparatus of claim 12, wherein
the holding member includes a first contacting surface and second contacting surface which has a curvature being different from a curvature of the first contacting surface.

16. The substrate processing apparatus of claim 11, wherein
the curvature of the concave curvature surface is appropriately the same as a curvature of the substrate.

17. The substrate processing apparatus of claim 11, wherein
the contact surface has a surface of a body with a straight fashion which extends in a vertical direction to a surface of the substrate.

18. The substrate processing apparatus of claim 12, wherein
the substrate holding section includes a rotation axis being a same direction of a rotation axis of the rotation driving section and rotates each of the holding members to change the concave curvature surface contacting to the substrate.

19. The substrate processing apparatus of claim 18, wherein
the holding member rotates around the rotation axis of the substrate holding section with a predetermined angle.

20. The substrate processing apparatus of claim 18, wherein
the contacting surface is formed on the substrate holding section and the substrate contact section rotates around the rotation axis of the substrate holding section by pressure of an outer portion.
